(19) United States
(12) Patent Application Publication
(10) Pub. No.: US 2006/0157869 A1
(43) Pub. Date: Jul. 20, 2006

(54) Semiconductor substrate with conductive bumps having a stress relief buffer layer formed of an electrically insulating organic material

(75) Inventors: Yuan-Chang Huang, Hsinchu (TW); Yao-Sheng Lin, Hsinchu (TW)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: Industrial Technology Research Institute

(21) Appl. No.: 11/347,942

(22) Filed: Feb. 6, 2006

Related U.S. Application Data
(63) Continuation-in-part of application No. 10/717,355, filed on Nov. 19, 2003, now abandoned.

(51) Int. Cl. H01L 23/48

(52) U.S. Cl. 257/779

(57) ABSTRACT

A microelectronic structure is provided having a semi-conducting substrate comprising circuits therein and a top surface, and at least one first conductive bump situated on the top surface. The conductive bump provides electrical communication to the circuits. The at least one conductive bump has a stress relief buffer layer formed of an electrically insulating organic material. The portions of the at least one conductive bump other than the stress relief buffer layer are a unitary structure. The top surface of the conductive bump is uncovered and directly exposed to its surroundings.

### CROSS-REFERENCE TO RELATED APPLICATION

This application is a continuation-in-part of copending U.S. application Ser. No. 10/717,355 filed Nov. 19, 2003, originally entitled “Conductive Bumps With Insulating Sidewalls And Method For Fabricating,” the entire disclosure of which is incorporated herein by reference.

### BACKGROUND OF THE INVENTION

1. Field of the Invention

The present invention generally relates to a microelectronic structure that is provided with conductive bumps on a surface for making electrical connection with other substrates and more particularly, relates to a microelectronic structure that is provided with a conductive bump having insulating sidewalls for making electrical communication with bond pads on another substrate such that any possible electrical short between the conductive bump and its immediately adjacent bump can be avoided. The invention further provides a method for fabricating the microelectronic structure that is equipped with the conductive bumps.

2. Background

In the recent development of integrated circuit (IC) chip mounting technologies, an IC chip is frequently bonded to another electronic substrate by establishing electrical communication between conductive bumps built on the IC chip and bond pads provided on the electronic substrate. When such bonding technique is used, an anisotropic conductive film (ACF) is frequently employed in-between the IC chip and the electronic substrate such that electrically conductive particles embedded in the ACF provide such electrical communication.

Referring initially to FIGS. 1A-1C, wherein a typical process for bonding a microelectronic structure to an electronic substrate is shown. The microelectronic structure 10 is equipped with a plurality of electrically conductive bumps 12 formed on a top surface for providing electrical communication to microelectronic circuits (not shown) in the microelectronic structure 10. The conductive bump 12 is built on a bond pad 14, a seed layer 16 and is insulated by a dielectric layer 18. The electronic substrate 20, on the other hand, is provided with a plurality of bond pads 22 formed on a top surface 24. The electronic substrate 20 may be advantageously a printed circuit board in one embodiment. An anisotropic conductive film 30 that has a multiplicity of electrically conductive particles 32 embedded in an electrically insulating material 34 is positioned on the top surface 24 of the electronic substrate 20.

After the microelectronic structure 10, the electronic substrate 20 and the ACF 30 are placed in a heated bonding device and a suitable pressure is applied to press the microelectronic structure 10 against the electronic substrate 20, an electronic assembly 40 is formed which is shown in FIG. 1C. As seen in FIG. 1C, electrical communication between the microelectronic structure 10 and the electronic substrate 20, is established by electrically conductive particles 32a, 32b and 32c which provide electrical conductance between the conductive bumps 12 and the bond pads 22.

The bonding method by using ACF can be efficient and low cost. However, since the distribution of the multiplicity of electrically conductive particles 32 can not be controlled in an orderly manner when it is dispersed and embedded in the insulating material 34, a cluster of the electrically conductive particles 32 frequently occurs which may cause an undesirable electrical short between adjacent conductive bumps 12. This is shown in FIG. 1D. While electrically conductive particles 32a, 32b and 32c provides desirable electrical communication between the conductive bumps 12 and the bond pads 22, electrically conductive particles 32d provides the undesirable electrical shorting between the two adjacent conductive bumps 12. When such electrical shorting occurs, the electronic circuits in the microelectronic structure 10 may be damaged or otherwise become non-functional. Such electrical shorting therefore must be avoided.

As one solution to the problem, ACF suppliers have developed an ACF film that has controlled pattern of distribution of the electrically conductive particles in the insulating material. However, such tightly controlled distribution ACF films are produced at very high cost and therefore, renders the bonding technique using the film impractical.

It is therefore an object of the present invention to provide a method of bonding an IC chip to an electronic substrate by using anisotropic conductive films therein-between, which does not have the drawbacks or shortcomings of the conventional method.

It is another object of the present invention to provide a method for bonding an IC chip to an electronic substrate by forming on the IC chip specially designed conductive bumps which do not short with immediately adjacent neighboring bumps.

It is a further object of the present invention to provide a microelectronic structure that has electrically conductive bumps formed on top wherein the bumps are formed with an insulating sidewall.

It is another further object of the present invention to provide a microelectronic structure that has electrically conductive bumps formed on top which have at least a section of its sidewall that is juxtaposed to an immediately adjacent bump formed of an insulating material.

It is still another object of the present invention to provide a microelectronic assembly formed by a microelectronic structure that has electrically conductive bumps formed on top which are substantially covered on the sidewalls by an electrically insulating material.

It is yet another object of the present invention to fabricate a microelectronic structure that has electrically conductive bumps formed on top which are covered on its sidewalls by an insulating material formed by a technique selected from the group consisting of polishing, dry etching, and lithography.

### BRIEF SUMMARY OF THE INVENTION

In accordance with the present invention, a microelectronic structure that is equipped with at least one conductive bump on a top surface wherein the at least one conductive bump has a sidewall formed of an electrically insulating material is provided.

In a preferred embodiment, a microelectronic structure is provided which includes a semi-conducting substrate having electronic circuits therein and a top surface; and at least one first conductive bump situated on the top surface providing electrical communication to the circuits, the at least one conductive bump has a sidewall formed of an electrically insulating material.

In the microelectronic structure, the sidewall is formed of an electrically insulating material which at least partially covers a periphery of the at least one conductive bump, or the electrically insulating material covers completely a periphery of the at least one first conductive bump while leaving a top surface of the at least one first conductive bump exposed. The sidewall may at least cover a section of the sidewall in the periphery of the at least one first conductive bump that is juxtaposed to a second conductive bump situated immediately adjacent to the at least one first conductive bump. The electrically insulating material may be an organic material or an inorganic material. The electrically insulating material may be a photosensitive material. The at least one first conductive bump may be formed of a conductive metal selected from the group consisting of Au, Ag, Pt, Pd, Al, Cu, Sn and alloys thereof. The at least one first conductive bump may have a height between about 5 μm and about 50 μm.

The present invention is further directed to a microelectronic assembly that includes a semi-conducting substrate that has at least one conductive bump situated on a top surface, the at least one conductive bump may have a sidewall formed of an electrically insulating material; a substrate that has at least one conductive pad situated on a top surface; and an anisotropic conductive film sandwiched in-between the semi-conducting substrate and the electronic substrate, the anisotropic conductive film includes at least one electrically conductive particle providing electrical communication between the at least one conductive bump and the at least one conductive pad.

In the microelectronic assembly, the semi-conducting substrate may be an integrated circuit chip and the electronic substrate may be a printed circuit board or glass substrate. The sidewall that is formed of an electrically insulating material at least partially covers a periphery of the at least one conductive bump, or covers completely a periphery of the at least one conductive bump, while leaving a top surface of the at least one conductive bump exposed. The at least one conductive bump may be formed of a conductive metal selected from the group consisting of Au, Ag, Pt, Pd, Al, Cu, Sn and alloys thereof.

The present invention is still further directed to a method for fabricating a microelectronic structure which can be carried out by the operating steps of providing a semi-conducting substrate including circuits therein; forming at least one first conductive bump on a top surface of the semi-conducting substrate; conformally depositing a layer of insulating material on the at least one first conductive bump and the top surface of the semi-conducting substrate; and removing selectively the layer of insulating material from a top surface of the at least one first conductive bump while leaving a sidewall of the at least one first conductive bump covered by the layer of insulating material.

In the method for fabricating a microelectronic structure, the removing step may be carried out by a method selected from the group consisting of polishing, dry etching and lithography, or by chemical mechanical polishing. The method may further include the step of forming the at least one first conductive bump to a height between about 5 μm and about 50 μm. The method may further include the step of forming the at least one first conductive bump from a material selected from the group consisting of Au, Ag, Pt, Pd, Al, Cu, Sn and alloys thereof. The method may further include the step of depositing conformally the layer of insulating material selected from the group consisting of organic materials and inorganic materials.

The present invention is still further directed to a method for fabricating a microelectronic structure that can be carried out by the operating steps of providing a semi-conducting substrate including circuits therein; forming at least one bump of a photosensitive material on a bond pad situated on the semi-conducting substrate, the photosensitive material is electrically insulating; patterning and developing the at least one bump such that only a sidewall remaining after the developing process; and filling a cavity formed by the sidewall by electroplating and forming at least one electrically conductive bump surrounded by the electrically insulating photosensitive material on its peripheral surface, the at least one electrically conductive bump is in electrical communication with the circuits in the semi-conducting substrate.

### BRIEF DESCRIPTION OF THE DRAWINGS

These and other objects, features and advantages of the present invention will become apparent from the following detailed description and the appended drawings in which:

FIGS. 1A-1D are enlarged, cross-sectional views illustrating a conventional bonding process for mounting a microelectronic structure to an electronic substrate by using an anisotropic conductive film.

FIGS. 2A-2C are enlarged, cross-sectional views illustrating a preferred embodiment of the present invention method for fabricating conductive bumps with insulating sidewalls by a polishing method.

FIGS. 3A-3B are enlarged, cross-sectional views illustrating an alternate embodiment of the present invention method utilizing dry etching.

FIGS. 4A and 4B are enlarged, cross-sectional views illustrating yet another embodiment of the present invention method utilizing photolithography.

FIG. 5A-5G are enlarged, cross-sectional views illustrating still another alternate embodiment of the present invention method utilizing electrodeposition.

FIGS. 6A-6C are enlarged, cross-sectional views illustrating a microelectronic structure and a microelectronic assembly, respectively, formed by the present invention method.

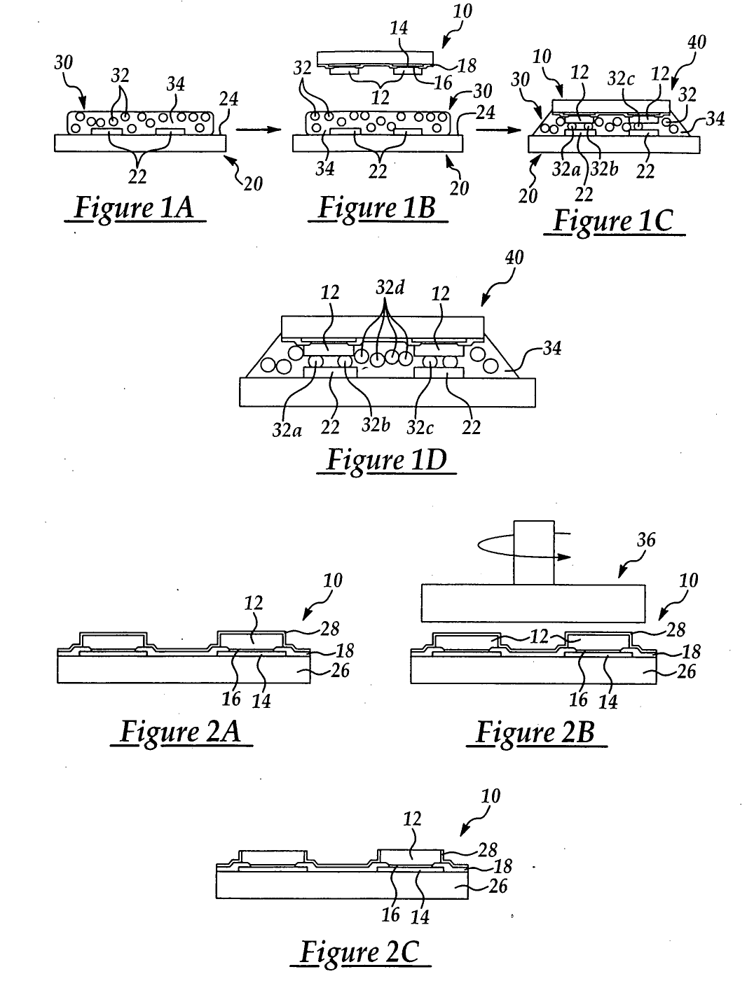

### DETAILED DESCRIPTION OF THE INVENTION

The present invention provides a microelectronic structure that is equipped on a top surface at least one conductive bump formed with insulating sidewalls. The insulating sidewalls are formed of an insulating material of either organic or inorganic base that at least partially covers a periphery of the at least one conductive bump. The insulating material, while covers either partially or completely a periphery of the at least one conductive bump, leaves a top surface of the at least one conductive bump exposed.

The electrically insulating material used in forming the insulating sidewall may also be a photosensitive material such that a sidewall may first be formed and then, an electrodeposition process may be used to fill the sidewall cavity and form a conductive bump. The conductive bump may be formed of a conductive metal material such as Au, Ag, Pt, Pd, Al, Cu, Sn and alloys thereof.

The present invention further discloses a microelectronic assembly that is formed by bonding together a semi-conducting substrate and an electronic substrate. The semi-conducting substrate may be an integrated circuit chip, while the electronic substrate may be a printed circuit board or glass substrate. The two parts are bonded together by sandwiching anisotropic conductive film therein-between. The semi-conducting substrate has at least one or a plurality of conductive bumps formed on a top surface wherein each of the conductive bumps are surrounded by an insulating sidewall formed of an electrically insulating material with the top of the bumps exposed for establishing electrical communication.

The present invention further discloses a method for fabricating a microelectronic structure that has conductive bumps formed on top with insulating sidewalls. The method may be carried out by first forming at least one conductive bump on the semi-conducting substrate, then conformally depositing a layer of insulating material on the at least one conductive bump, and then removing selectively the layer of insulating material from a top surface only of the at least one conductive bump. The removal process may be conducted by a technique such as polishing or chemical mechanical polishing, dry etching or lithography.

In another method for fabricating the microelectronic structure having conductive bumps with insulating sidewalls on top, at least one bump formed of a photosensitive material is formed on a bond pad, the photosensitive material is electrically insulating. The at least one bump is then patterned and developed such that only a sidewall of the bump remains after the developing process. An electrodeposition process is then carried out to fill a cavity formed by the sidewall of the bump forming an electrically conductive bump of a conductive metal surrounded by the electrically insulating photosensitive material on its sidewalls. The electrically conductive bump formed is in electrical communication with the circuits pre-formed in the semi-conducting substrate.

The method for forming conductive bumps with insulating sidewalls on a microelectronic structure can be carried out by many different techniques. A first technique, is shown in the present invention preferred embodiment in FIGS. 2A-2C.

In this preferred embodiment, a microelectronic structure, i.e. an integrated circuit (IC) chip 10 is first provided. The IC chip 10 is built on a silicon substrate 26 that has a plurality of bond pads 14 on top. A seed layer 16 of the same material used in forming the conductive bumps 12 is then deposited and patterned on the bond pads 14. The conductive bump may be suitably formed of a conductive metal such as Au, Ag, Pt, Pd, Al, Cu, Sn and alloys thereof. A dielectric layer 18 is used to insulate the bond pads 14 from each other. After an insulating material layer is blanket deposited on top of the microelectronic structure 10, a polishing process is used to remove the insulating material layer 28 that is situated on top of the conductive bumps 12. This is shown in FIG. 2B. A polishing head 36 equipped with a polishing pad (not shown) in a chemical mechanical polishing apparatus is used to remove the layer of insulating material 28 from the top surfaces of the conductive bumps 12.

The insulating material layer 28 may be formed of an organic material and applied by a technique such as spin-coating, printing, etc., or an inorganic material which is applied by a technique such as chemical vapor deposition, physical vapor deposition, etc. A suitable thickness for the insulating material layer is between about 0.2 .mu.m and about 2 .mu.m. A suitable height of the conductive bumps 12 is in-between about 5 μm and about 50 μm. By utilizing a chemical mechanical polishing method, best flatness of conductive bumps can be obtained and thus the yield of ACF bonding process is improved. A finished product is shown in FIG. 2C.

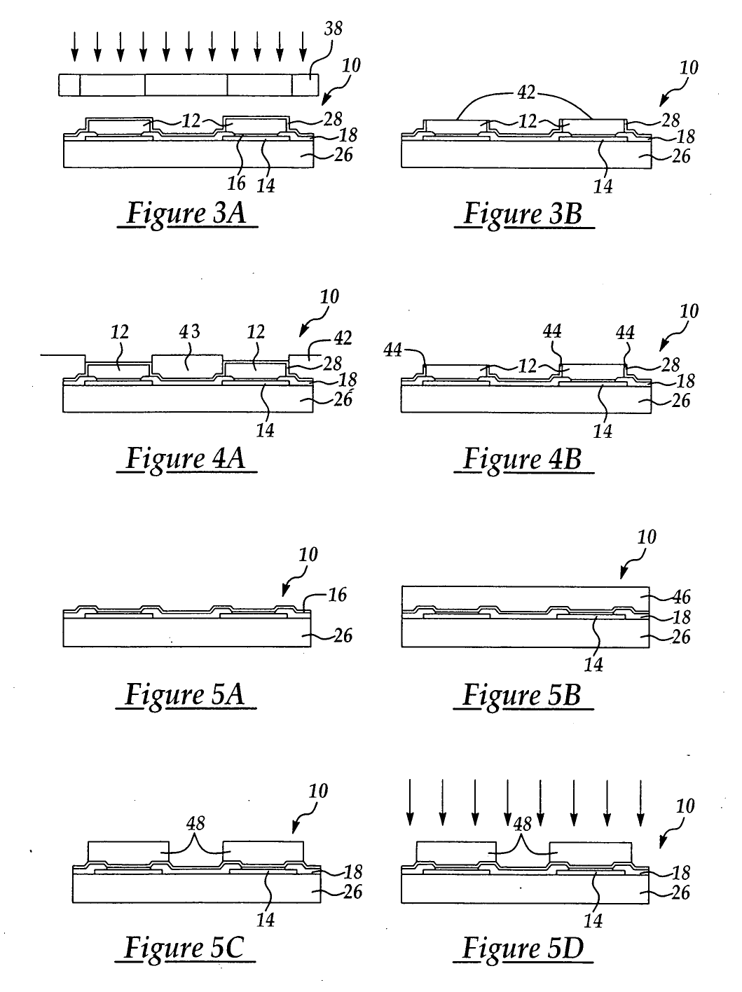

Alternate embodiments of the present invention method for forming microelectronic structures that have conductive bumps with insulating sidewalls is shown in FIGS. 3A-3B and FIGS. 4A-4B. In the process shown in FIGS. 3A-3B, the insulating material layer 28 is formed of a photosensitive organic material by a suitable technique, such as spin-coating, printing, etc. A photomask layer 38 is then used for the conductive bumps 12 to expose the photosensitive insulating material layer 28. This is shown in FIG. 3A. After the exposed photosensitive insulating material layer 28 is developed, only the top portion of layer 28 is removed. A top surface 42 of the conductive bumps 12 is thus exposed for making electrical contact with bond pads on an electronic substrate through an ACF layer.

In still another alternate embodiment, shown in FIGS. 4A-4B, a dry etch method is used for forming the conductive bumps with insulating sidewalls. A layer of photoresist 43 is first deposited and patterned on the microelectronic structure 10. A plasma enhanced etching process is then carried out to etch away the layer of insulating material 28 on top of the conductive bumps 12, resulting in the final structure shown in FIG. 4B with only an insulating sidewall surrounding the conductive bumps 12 left.

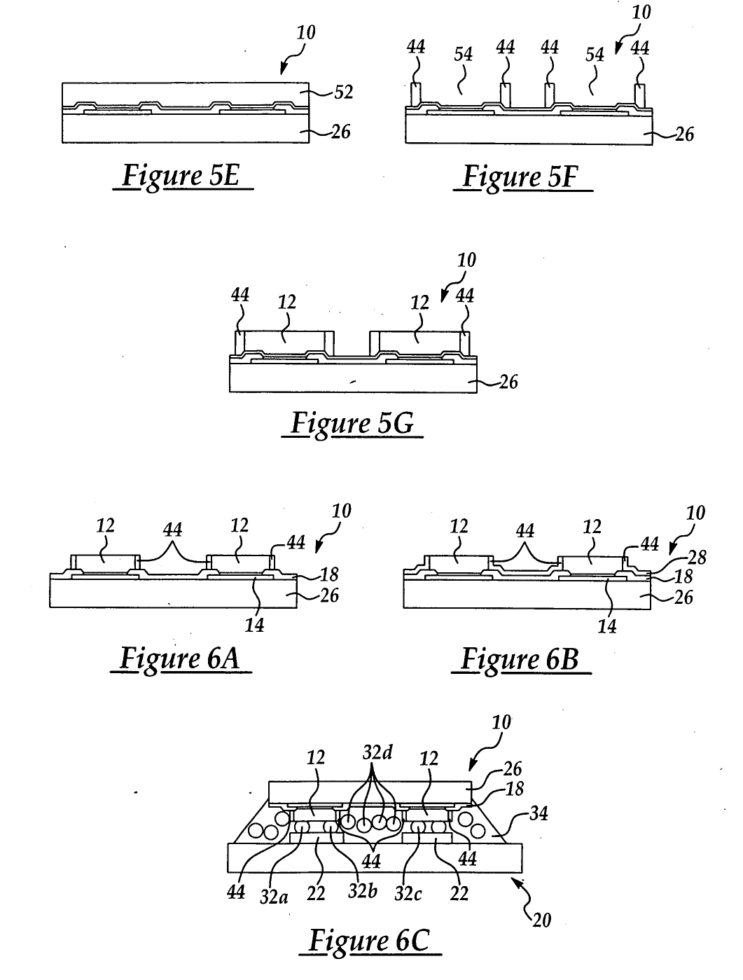

In still another method for preparing the present invention microelectronic structure 10 that has conductive bumps 12 formed on top, each surrounded by insulating material layer 44, as shown in FIGS. 5A-5G, an electrodeposition process is used in forming the conductive bumps 12. The microelectronic structure 10 is first deposited with a blanket seed layer 16, as shown in FIG. 5A. On top of the seed layer 16, is then deposited a thick photoresist layer 46. After the photoresist layer 46 is patterned and developed, as shown in FIG. 5C, only the portions 48 of the photoresist layer 46 are left covering the bond pads 14. The seed layer 16 that is not covered by the portions 48 are then etched away in a dry etching process, shown in FIG. 5B. A second photoresist layer 52 is then deposited to be patterned and form sidewall 44 of the photoresist bumps 48. This is shown in FIGS. 5E and 5F. In the final step of the process, an electrodeposition method is carried out to fill the cavities 54 in the sidewall 44 with a conductive metal such as Au. Other suitable conductive metals such as Ag, Pt, Pd, Al, Cu, Sn and alloys thereof, may also be used in the electrodeposition process. The final microelectronic structure 10 is thus formed with conductive bumps 12 and sidewall 44 surrounding the peripheral surface, except the top surface, of the conductive bumps. This is shown in FIG. 5G.

The present invention microelectronic structure 10 shown in two different configurations in FIGS. 6A and 6B, while FIG. 6C illustrates the desirable effect of the present invention structure. In FIG. 6A, the insulating material only surrounds the conductive bump 12, while in the second configuration shown in FIG. 6B, the insulating material layer 28 remains on the microelectronic structure 10.

FIG. 6C illustrates the desirable effect of the present invention conductive bumps 12 that has sidewall 44 formed on the sidewall. It is seen that while conductive particles 32d are clustered together in the insulating material 34 that bonds the microelectronic structure 10 to the electronic substrate 20, the sidewall 44 prevents a short between the two conductive bumps 12.

In one preferred embodiment of the present invention, the sidewall functions as a stress relief buffer layer or an insulation buffer layer, and is formed of a high-polymer organic material such as polyimide, acrylic or asepoxy. Polyimide, for example, has a coefficient of thermal expansion (CTE) of about 20 ppm to about 40 ppm. One advantage of using such organic materials is that their CTE is closer to the CTE of their high-polymer surroundings after being packaged or filled with an anisotropic conductive film (ACF) than certain inorganic materials, such as silicon oxide or silicon nitride. For example, the CTE of the high-polymer surroundings is about 40 ppm to about 80 ppm. Since the CTE of polyimide is about 20 ppm to about 40 ppm, it can act as a buffer between the high-polymer surroundings or ACF, and metals. The CTE of inorganic ceramic materials, such as silicon oxide or silicon nitride, that are used as a sidewall insulating layer in U.S. Patent Application Publication No. 2002/0048924 (Lay et al.) is less than about 8 ppm, and thus cannot provide an effective stress relief buffer layer.

While the present invention has been described in an illustrative manner, it should be understood that the terminology used is intended to be in a nature of words of description rather than of limitation.

Furthermore, while the present invention has been described in terms of a preferred and alternate embodiment, it is to be appreciated that those skilled in the art will readily apply these teachings to other possible variations of the inventions.

The embodiment of the invention in which an exclusive property or privilege is claimed are defined as follows.

What is claimed is:

1. A microelectronic structure comprising:
(a) a semi-conducting substrate comprising circuits therein and a top surface; and
(b) at least one first conductive bump situated on said top surface providing electrical communication to said circuits, said at least one conductive bump having a stress relief buffer layer formed of an electrically insulating organic material, the portions of the at least one conductive bump other than the stress relief buffer layer being a unitary structure, the top surface of the conductive bump being uncovered and directly exposed to its surroundings.

2. The microelectronic structure according to claim 1, wherein said stress relief buffer layer formed of the electrically insulating material at least partially covers a periphery of said at least one first conductive bump.

3. The microelectronic structure according to claim 1, wherein said stress relief buffer layer formed of the electrically insulating material covers completely a periphery of said at least one first conductive bump while leaving the top surface of said at least one first conductive bump exposed.

4. The microelectronic structure according to claim 1, wherein said stress relief buffer layer formed of the electrically insulating material at least covers a section of said stress relief buffer layer in said periphery of said at least one first conductive bump that is juxtaposed to a second conductive bump situated immediately adjacent to said at least one first conductive bump.

5. The microelectronic structure according to claim 1, wherein said electrically insulating material comprises a photosensitive material.

6. The microelectronic structure according to claim 1, wherein said at least one first conductive bump is formed of a conductive metal selected from the group consisting of Au, Ag, Pt, Pd, Al, Cu, Sn and alloys thereof.

7. The microelectronic structure according to claim 1, wherein said at least one first conductive bump having a height between about 5 μm and about 50 μm.

8. The microelectronic structure according to claim 1 wherein the stress relief buffer layer is a sidewall of the at least one conductive bump.

9. The microelectronic structure according to claim 1 wherein the electrically insulating organic material is polyimide.

10. The microelectronic structure according to claim 1 wherein the electrically insulating organic material is acrylic.

11. The microelectronic structure according to claim 1 wherein the electrically insulating organic material is asepoxy.

12. A microelectronic assembly comprising:
(a) a semi-conducting substrate having at least one conductive bump situated on a top surface, said at least one conductive bump having a stress relief buffer layer formed of an electrically insulating organic material, the portions of the at least one conductive bump other than the stress relief buffer layer being a unitary structure, the top surface of the conductive bump being uncovered and directly exposed to its surroundings;
(b) an electronic substrate having at least one conductive pad situated on a top surface; and
(c) an anisotropic conductive film sandwiched in-between said semi-conducting substrate and said electronic substrate, said anisotropic conductive film comprising at least one electrically conductive particle providing electrical communication between said at least one conductive bump and said at least one conductive pad, the top surface of the conductive bump thereby being directly exposed to the at least one particle in the anisotropic conductive film.

13. The microelectronic assembly according to claim 12, wherein said semi-conducting substrate is an integrated circuit chip and said electronic substrate is a printed circuit board or a glass substrate.

14. The microelectronic assembly according to claim 12, wherein said stress relief buffer layer formed of the electrically insulating material at least partially covers a periphery of said at least one conductive bump.

15. The microelectronic assembly according to claim 12, wherein said stress relief buffer layer formed of the electrically insulating material covers completely a periphery of said at least one conductive bump while leaving the top surface of said at least one conductive bump exposed.

16. The microelectronic assembly according to claim 12, wherein said at least one conductive bump is formed of a conductive metal selected from the group consisting of Au, Ag, Pt, Pd, Al, Cu, Sn and alloys thereof.

17. The microelectronic assembly according to claim 12 wherein the stress relief buffer layer is a sidewall of the at least one conductive bump.

18. The microelectronic structure according to claim 12 wherein the electrically insulating organic material is polyimide.

19. The microelectronic structure according to claim 12 wherein the electrically insulating organic material is acrylic.

20. The microelectronic structure according to claim 12 wherein the electrically insulating organic material is asepoxy.
